(19) United States
(12) Patent Application Publication
(10) Pub. No.: US 2010/0308300 A1
(43) Pub. Date: Dec. 9, 2010

(54) INTEGRATED CIRCUIT LIGHT EMISSION DEVICE, MODULE AND FABRICATION PROCESS

(75) Inventor: Shaoher X. Pan, San Jose, CA (US)

Correspondence Address: FISH & RICHARDSON P.C. (SV), PO BOX 1022, MINNEAPOLIS, MN, 55440-1022, US

(73) Assignee: SiPhoton, Inc.

(21) Appl. No.: 12/480,463

(22) Filed: Jun. 8, 2009

(51) Int. Cl. H01L 33/00; H01L 21/66; H01L 21/78

(52) U.S. Cl. 257/13; 257/88; 257/98; 438/14; 438/33; 257/99; 257/E21.599; 257/E21.529; 257/E33.061; 257/E33.055; 257/E33.003

(57) ABSTRACT

An integrated circuit device, which can be a light emission device such as a light emitting diode (LED), comprises a substrate, a plurality of device layers formed on a first surface of the substrate, including a first device layer and a second device layer, a first electrode formed on the first device layer, and a second electrode formed on a second surface of the substrate which is parallel and opposite to the first surface of the substrate. A plurality of substantially identical such devices can formed on a semiconductor wafer, where one or both of the first and second electrodes are shared by the plurality of devices prior to dicing the wafer. All of the devices can be tested simultaneously on the wafer, prior to dicing. Formation of the electrodes on opposite sides of the substrate allow the device to be directly connected to a mounting substrate, without any wire bonding.

### BACKGROUND

The present patent application is related to integrated circuit (IC) light emission devices.

Solid-state light sources, such as light emitting diodes (LEDs) and laser diodes, can offer significant advantages over other forms of lighting, such as incandescent or fluorescent lighting. For example, when LEDs or laser diodes are placed in arrays of red, green and blue elements, they can act as a source for white light or as a multi-colored display. In such configurations, solid-state light sources are generally more efficient and produce less heat than traditional incandescent or fluorescent lights. Although solid-state lighting offers certain advantages, conventional semiconductor structures and devices used for solid-state lighting are relatively expensive. The high cost of conventional solid-state light emission devices is partially related to the fact that the manufacturing process for conventional solid-state light emission devices is complicated and time-consuming. The details of the manufacturing process are dictated by the structure of the conventional solid-state light emission devices.

Referring to FIG. 1, a conventional LED structure 100 includes a substrate 105, which may be formed of sapphire, silicon carbide, or spinel, for example. A buffer layer 110 is formed on the substrate 105. The buffer layer 110 serves primarily as a wetting layer, to promote smooth, uniform coverage of the sapphire substrate. The buffer layer 110 is typically formed of GaN, InGaN, AlN, or AlGaN and has a thickness of about 100-500 Angstroms. The buffer layer 310 is typically deposited as a thin amorphous layer using Metal Organic Chemical Vapor Deposition (MOCVD).

A p-doped Group III-V compound layer 120 is formed on the buffer layer 110. The p-doped Group III-V compound layer 120 is typically made of GaN. An InGaN quantum-well layer 130 is formed on the p-doped Group III-V compound layer 120. An active Group III-V compound layer 140 is then formed on the InGaN quantum-well layer 130. An n-doped Group III-V compound layer 150 is formed on the layer 140. The p-doped Group III-V compound layer 120 is n-type doped. A p-electrode 160 (anode) is formed on the n-doped Group III-V compound layer 150. An n-electrode 170 (cathode) is formed on the first Group III-V compound layer 120.

A problem with the conventional manufacturing process, associated with devices such as shown in FIG. 1, is that it requires a series of selective etch stages to enable the cathode 170 to be formed on the p-doped Group III-V compound layer 120. These selective etch stages are complicated and time-consuming and, therefore, make the overall manufacturing process more expensive.

Another problem with the conventional process is that testing of the devices to detect manufacturing defects and to determine device characteristics is done only after dicing a wafer into chips (dice) and packaging (e.g., wire bonding) the chips. In other words, testing is done individually on each chip. As a result, even defective chips are packaged (since they have not yet been identified at the packaging stage), which results in time, effort and material being wasted on packaging defective chips. Furthermore, the need to test all of the chips individually makes the overall manufacturing process more time-consuming and complicated.

In addition, a problem associated with the device in FIG. 1 is that the cathode 170 blocks some of the emitted light from leaving the device. This effect reduces the overall efficiency of the device. An approach which has been used to mitigate this effect is to grind down the substrate 105 from the bottom at the end of the manufacturing process, to a very small thickness, so that light can exit through the bottom surface of the substrate. However, this makes the manufacturing process even more complicated and time-consuming and wastes substrate material.

### SUMMARY

Introduced here is an integrated circuit device, which can be a light emission device such as an LED, in which the electrodes are formed on opposite sides of the substrate, and opposite sides of the active (light emission) layers of the device. For example, a first electrode (e.g., the anode) can be formed over the active layers that have been grown on a top surface of the substrate and a second electrode (e.g., the cathode) is formed on a bottom surface of the substrate. This approach eliminates the need for a complicated, time-consuming and expensive multistage selective etch process, such as employed in a conventional LED manufacturing process for purposes of forming the cathode. Furthermore, this approach reduces waste of material (e.g., semiconductor substrate), since no substrate grinding is needed. In addition, because one of the electrodes is formed on the bottom surface of the substrate, that electrode does not block light generated by the active layers of the device.

Formation of the electrodes on opposite sides of the substrate as described herein also allows a plurality of these devices to be formed on a semiconductor wafer, where all such devices on the wafer can share their first and second electrodes on the wafer. This approach allows all of the devices to be tested for manufacturing defects simultaneously on the wafer, which simplifies and shortens testing. Furthermore, no time and effort is wasted in packaging (e.g., wire bonding) defective devices. Moreover, this technique allows such a device to be packaged into an operable module by directly connecting it to a mounting substrate, without the use of any wire bonding, which further shortens and simplifies the manufacturing process.

### BRIEF DESCRIPTION OF THE DRAWINGS

One or more embodiments of the present invention are illustrated by way of example and not limitation in the figures of the accompanying drawings, in which like references indicate similar elements and in which:

FIG. 1 is a cross-sectional view of a conventional LED structure;

FIG. 2 is a perspective view of a light emission device in accordance with an embodiment of the present application;

FIG. 3 is a cross-sectional view of the light emission device along line A-A in FIG. 2;

FIG. 4 is a detailed cross-sectional view of the top portion of the light emission device in FIG. 3;

FIG. 5 is a detailed cross-sectional view of the bottom portion of the light emission device in FIG. 3;

FIG. 6A is a schematic cross-sectional view of the light emission device along line A-A in FIG. 2, according to one embodiment;

FIG. 6B is a schematic cross-sectional view of the light emission device along line A-A in FIG. 2, according to an alternative embodiment;

FIG. 7 is a perspective view of a 2×2 array of light emission structures fabricated on a substrate in accordance with the present application;

FIG. 8 is a partial cross-sectional view of the light emission structures along line B-B in FIG. 7;

FIGS. 9A through 9D are cross-sectional views at different steps of forming the light emission device of FIGS. 2 and 6;

FIG. 10 is a flowchart showing a process for fabricating the light emission devices; and

FIG. 11 shows a technique for packaging the light emission device of FIG. 2 into a module.

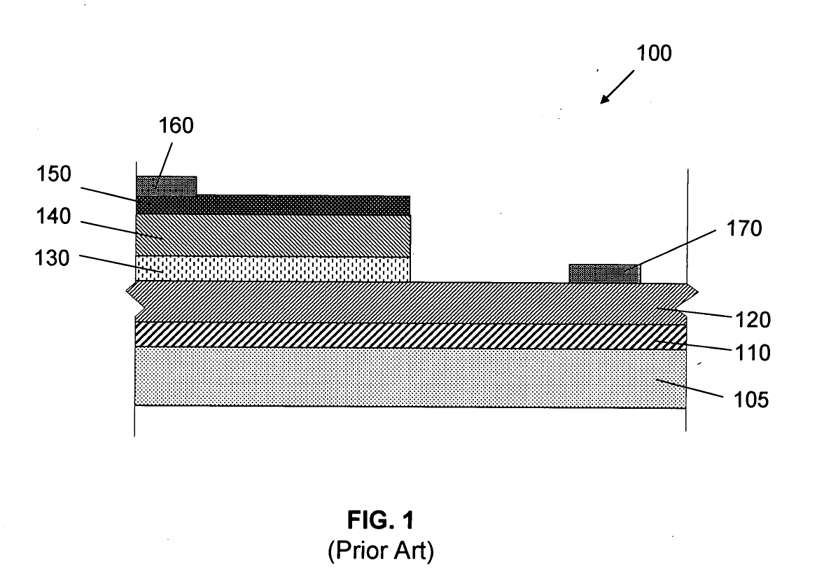

### DETAILED DESCRIPTION

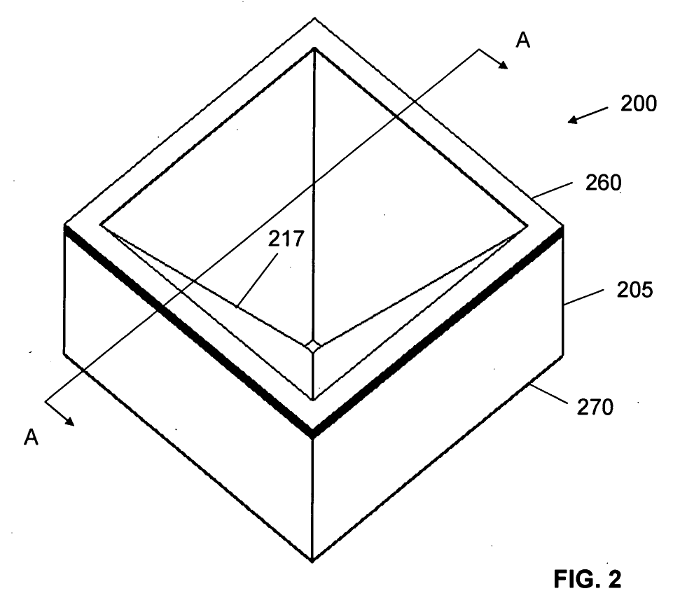

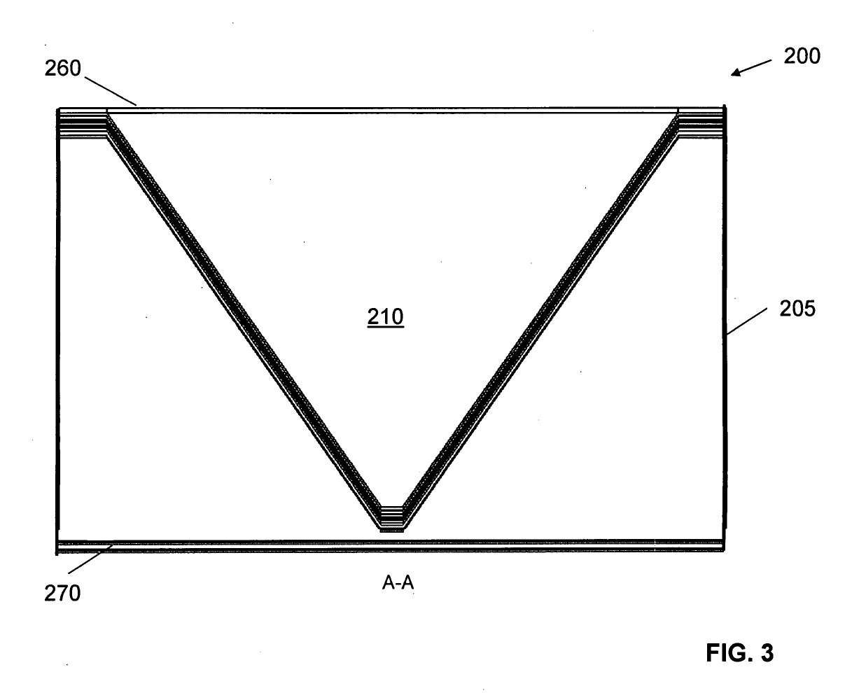

FIG. 2 shows a perspective view of a light emission device 200 in accordance with the technique introduced here. FIG. 3 is a cross-sectional view of the light emission device 200 along line A-A in FIG. 2. The device 200 includes a semiconductor substrate 205, a trench 210 formed in the top surface of the semiconductor substrate, a first electrode (anode) 260 formed around the edge of the trench 210, and a second electrode (s) 270 formed on a bottom side of the substrate 205. The sloped surfaces of trench 210 allow the light emission device 200 to produce significantly higher emission light intensity than conventional LED devices. Additional description of the structure, fabrication method and theory behind the light emission device shown in FIG. 2 are set forth in co-pending U.S. patent application Ser No. 12/177,114 by S. Pan, filed on Jul. 21, 2008 and entitled, “Light Emission device”, the disclosure of which is incorporated by reference herein.

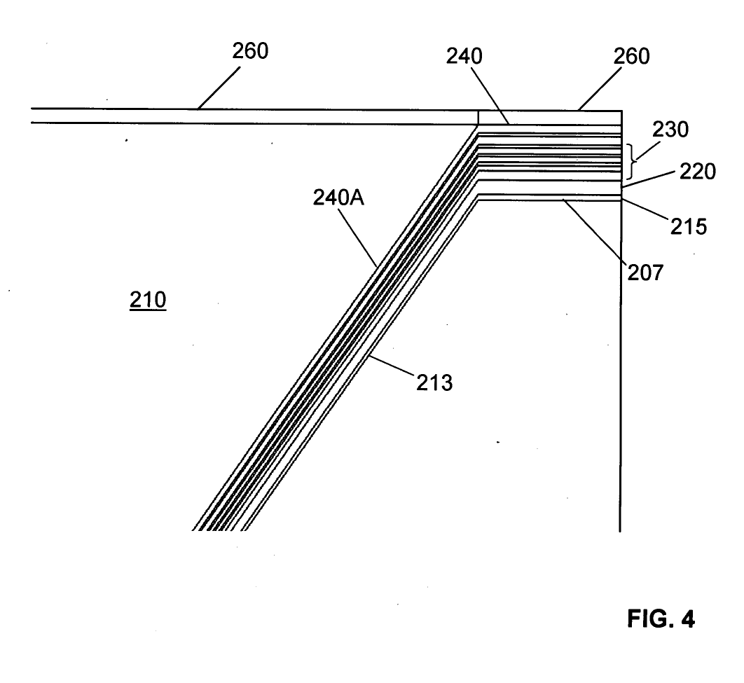

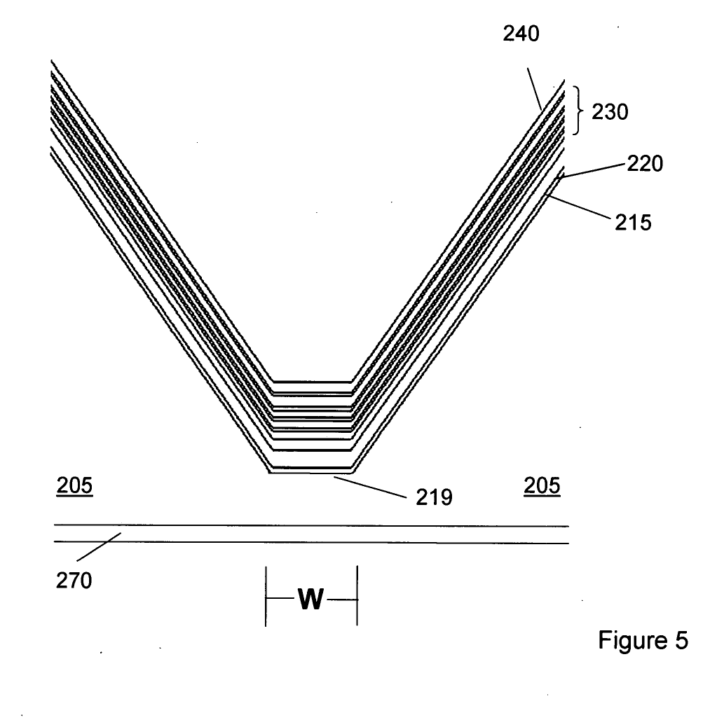

Referring to FIGS. 2 through 5, the light emission device 200 is formed on substrate 205, which has an upper surface 207 (FIG. 4). The light emission device 200 includes trench 210 in the substrate 205 below the upper surface 207. The trench 210 has one or more trench surfaces 213 (FIG. 4) at a slope relative to the upper surface 207. The trench 210 can also have a bottom surface 219 that is parallel to the upper surface 207. The area of the bottom surface 219 can be kept smaller than 20% of one of the trench surfaces 213. The substrate 205 can have a diamond type crystal structure and can be silicon based: the upper surface 207 can be parallel to the (100) crystalline plane. A trench surface 213 can be parallel to the (111) crystalline surface. Alternatively, the upper surface 207 can be parallel to the (111) crystalline plane, and the trench surface 213 can be parallel to the (100) crystalline surface. The trench 210 thus can have the shape of an inverted pyramid or a truncated inverted pyramid in the substrate 205, which forms a square opening in the upper surface 207. An internal edge 217 is formed at the intersection of two adjacent trench surfaces 213. The substrate 205 can have a rectangular or square shape having an outer edge 208. The light emission device 200 can be fabricated together with a batch of other light emission devices on a semiconductor wafer, and diced to form separate dies. The light emission device 200 can have a rectangular or square die shape defined by a planar area in the plane parallel to the upper surface 207.

The light emission device 200 includes: a reflective buffer layer 215 on the upper surface 207 and the trench surfaces 213; a lower Group III-V compound layer 220 on the reflective buffer layer 215; one or more quantum-well layers 230 on the lower Group III-V compound layer 220, where the quantum-well layers 230 collectively are a light emission layer; and an upper Group III-V compound layer 240. The lower Group III-V compound layer 220 and the upper Group III-V compound layer 240 each include a group III element and a group V element. The group III element is typically gallium. The group V element is typically nitride. Group III-V compounds suitable for the lower Group III-V compound layer 220 and the upper Group III-V compound layer 240 can include GaN or InGaAlN. The lower Group III-V compound layer 220 and the upper Group III-V compound layer 240 can be respectively n-type and p-type doped. The portion of the upper Group III-V compound layer 240 over the trench surface 213 is referred to as a sloped upper Group III-V compound layer 240A and is oriented at an angle relative to the upper surface 207 of the substrate 205. The light emission device 200 also includes a lower electrode 270 on the bottom surface of the substrate 205, and an upper electrode 260 on the upper Group III-V compound layer 240.

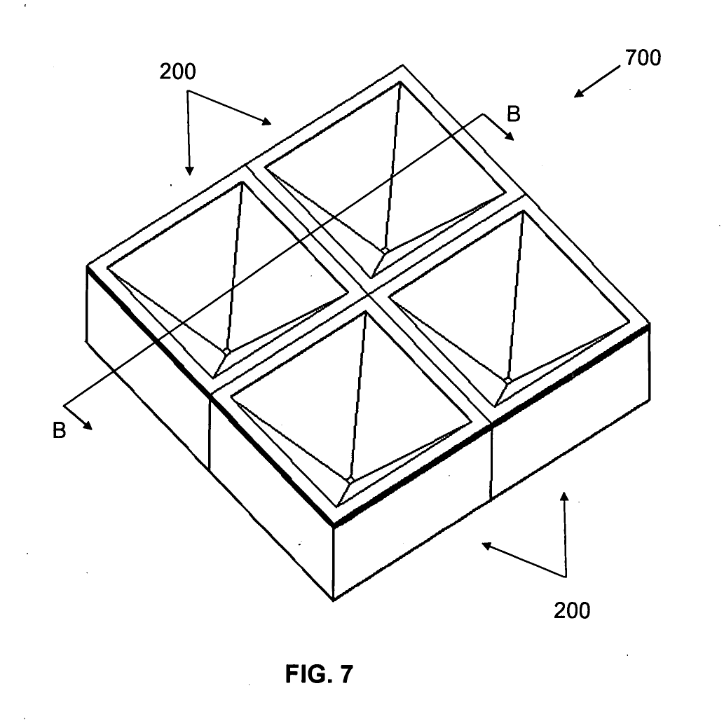

In some embodiments, as shown in FIG. 7, an array of multiple light emission devices 200 is formed on a semiconductor wafer 700. The light emission devices 200 can be located in a matrix on a semiconductor wafer. The light emission devices 200 can be used collectively as a single larger light emission device, or they can be separated by cutting and dicing to form physically separate light emission devices identical or similar to the light emission device 200.

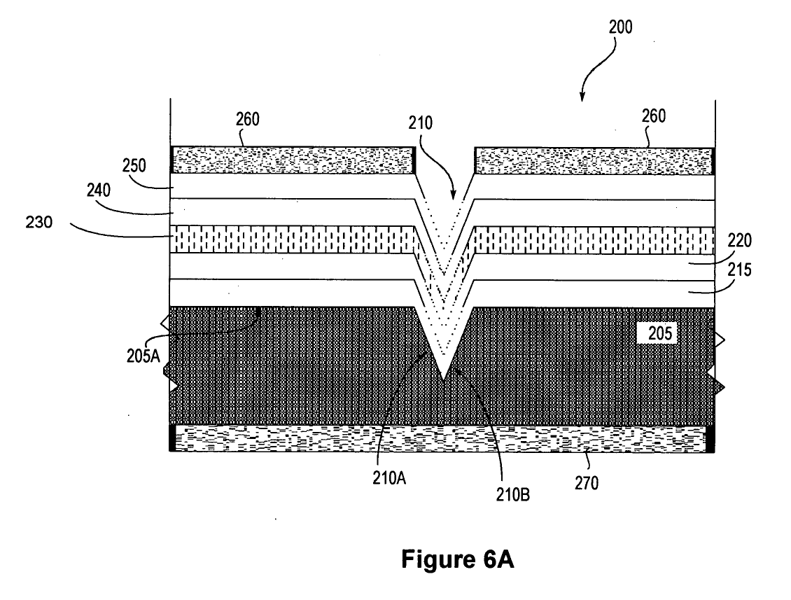

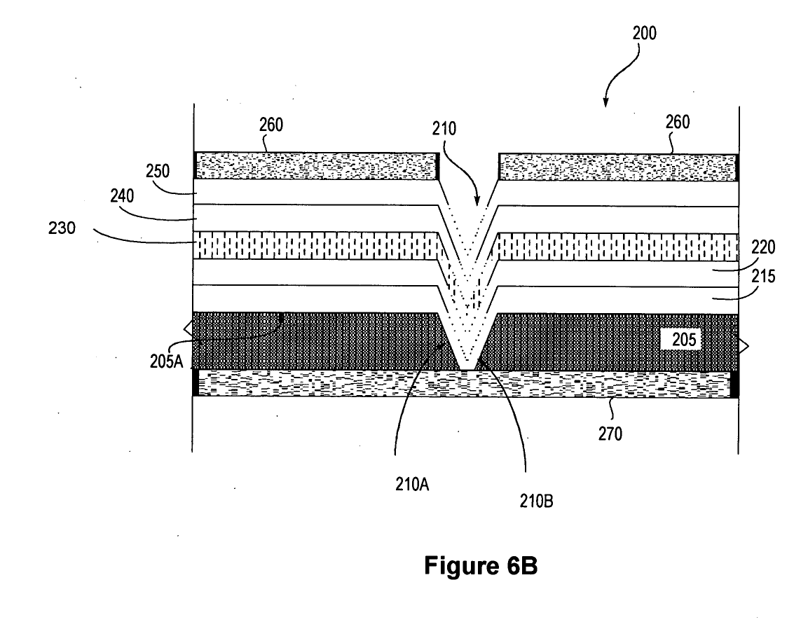

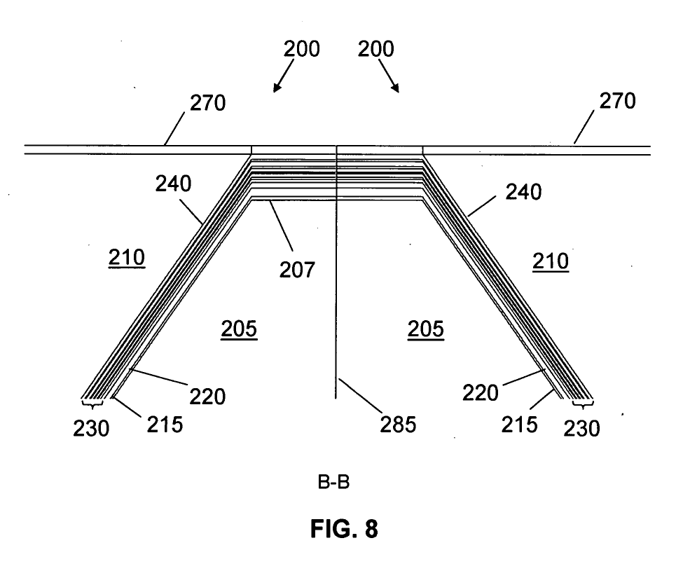

Referring to FIGS. 6 and 8, the light emission layers of devices 200 can be formed on trenches 210 in a substrate 205. The substrate 205 can be formed by silicon, silicon oxide, gallium nitride, silicon carbide, sapphire, or glass. The substrate 205 can also be formed by a double-layer structure such as a silicon layer on glass, or simply a silicon-on-insulator (SOI) wafer. The silicon layer can have a (100) upper surface. The thickness of the silicon layer can be used to define the depth of a trench. For a silicon based substrate, the substrate 205 can have an upper surface 205A in the (100) crystalline plane direction. The surfaces 210A, 210B of the trench 210 can be along the (111) crystalline plane direction. The substrate 205 can further be a doped silicon base substrate to form an electrically conductive substrate, which allows the second electrode 270 of the light emitting device to be on the opposite side of the substrate as the light emission layers. The substrate 205 can also include a complimentary metal oxide semiconductor (CMOS) material and a CMOS electric circuitry for driving and controlling the light emission device 200.

A reflective buffer layer 215 is formed on the surface 205A of the substrate 205 and the sloped surfaces 210A, 210B in the trenches 210. A function of the reflective buffer layer 215 is to reflect light emitted by the light emission quantum well layer 230 to the light emitting device surfaces and away from the substrate 205 to prevent the emitted light from being absorbed by the substrate 205. For example, the substrate 205 can be a doped silicon based conductive substrate, which absorbs light in the visible light range. The reflective buffer layer 215 can have a reflectance coefficient higher than 30%, 50%, or 70% in the spectral range for the emitted light from the light emission quantum well 230.

The reflective buffer layer 215 can be deposited on the substrate 205 using Metal-Organic Chemical Vapour Deposition (MOCVD), atomic layer deposition (ALD), physical vapor deposition (PVD), or Chemical Vapor Deposition (CVD) in a vacuum chamber maintained at a temperature in the range of 550° C. to 850° C., such as about 700° C. The reflective buffer layer 215 is electrically conductive. Most common reflective buffer layers are composed of multilayer of reflective metals and their nitrides in order to be electrically conductive. The thickness of each layer is calculated from reflective index of the materials for a specific wavelength of the light to be reflected. The reflective buffer layer 215 can have a thickness of about 200 to 200,000 Angstroms such as 1000 to 10,000 Angstroms. The reflective buffer layer 215 can wet and form a uniform layer on the substrate 205. The reflective buffer layer 215 can also have crystal structures with lattices expitaxially matched to the substrate 205 and the lower Group III-V compound layer 220 (described below).

The PVD, CVD, MOCVD, or ALD formation of the reflective buffer layer 215 can involve the use of TaN or TiN and a layer thickness of 10 to 100 angstromes. Atomic layer deposition (ALD) is a “nano” technology, allowing ultra-thin films of a few nanometers to be deposited in a precisely controlled way. ALD has the beneficial characteristics of self-limiting atomic layer-by-layer growth and is highly conformal to the substrate. For the formation of buffer layer in the light emission devices, ALD can use two or more precursors such as liquid halide or organometallic in vapor form. The ALD can involve heat to dissociate the precursors into the reaction species. One of the precursors can also be a plasma gas. By depositing one layer per cycle, ALD offers extreme precision in ultra-thin film growth since the number of cycles determines the number of atomic layers and therefore the precise thickness of deposited film. Because the ALD process deposits precisely one atomic layer in each cycle, complete control over the deposition process is obtained at the nanometer scale. Moreover, ALD has the advantage of being capable of substantially isotropic depositions. ALD is therefore beneficial for depositing buffer layers on the sloped surfaces 210A and 210B in the V-shape trenches, and the vertical surfaces in a U-shape trench.

A lower Group III-V compound layer 220 is formed on the reflective buffer layer 215. The lower Group III-V compound layer 220 can be formed by silicon doped n-GaN. The lower Group III-V compound layer 220 can have a thickness in the range of 1 to 50 microns, such as 10 microns.

The material for the reflective buffer layer 215 is selected to satisfy the requirements of high reflectivity, electrically conductive, and lattice matching with the substrate 205 and a lower Group III-V compound layer 220. For example, the reflective buffer layer 215 can be formed by Al, aluminum nitride, Al silicide, Ag, Ag oxide, Au, Au nitride, and their alloys of Al, Au and Ag. The reflective buffer layer 215 can be also formed by one or more materials such as TaN, TiN, GaN, ZnO, AlN, HfN, AlAs, or SiC. The reflective buffer layer 215 can have a thickness in the range of 200 to 200,000 Angstroms, such as 1,000 to 10,000 Angstroms. Each reflective layer 215 includes multiple layers of metal and its nitride thin-films to have a total reflection of a specific wavelength of the emitted light. The thickness of each metal layer or its nitride layer is in the order of monolayer of materials calculated from the optical property of the thin-film materials.

A quantum-well layer 230 is formed on the lower Group III-V compound layer 220. The quantum-well layer 230 can be made of InN or InGaN with a thickness in the range of 5 to 200 Angstroms, such as 50 Angstroms. An upper Group III-V compound layer 240 is formed on the quantum-well layer 230. The upper Group III-V compound layer 240 can be formed by p-type doped GaN such as Al_{0.1}Ga_{0.9}N. The upper Group III-V compound layer can be an aluminum doped p-GaN layer 240 having a thickness in the range of 0.1 to 10 microns, such as 1 micron. The quantum-well layer 230 forms a quantum well between the lower Group III-V compound layer 220 and the upper Group III-V compound layer 240. A conductive layer 250 is optionally formed on the upper Group III-V compound layer 240. The conductive layer 250 is at least partially transparent. Materials suitable for the conductive layer 250 can include ITO or a thin layer p-type ohmic metal such as Ni/Au.

An upper electrode 260 can be formed on the conductive layer 250 (or the upper Group III-V compound layer 240 in absence of the conductive layer 250). A lower electrode 270 is formed on the bottom surface of the substrate 205. The upper electrode 260 and lower electrode 270 can be referred to as the p-electrode and n-electrode, or anode and cathode, respectively, as henceforth assumed in this description to facilitate explanation. Note, however, that in other embodiments the upper electrode 260 can be n-type (i.e., the cathode) while the lower electrode 270 is p-type (i.e., the anode). The use of transparent ITO material in the conductive layer 250 can significantly increase the conductivity between the electrode 260 and the upper Group III-V compound layer 240 while maximizing the transmission light out of the upper surface of the conductive layer 250 emitted from the quantum-well layer 230.

The quantum-well layer 230 can form a quantum well for electric carriers in between the lower Group III-V compound layer 220 and the upper Group III-V compound layer 240. An electric voltage can be applied across the lower electrode 270 and the upper electrode 260 to produce an electric field in the quantum-well layer 230 to excite carriers in the quantum well formed by the quantum-well layer 230, forming a quantum well for electric carriers in between the lower Group III-V compound layer 220 and the upper Group III-V compound layer 240. The recombinations of the excited carriers can produce light emission. The emission wavelengths are determined mostly by the bandgap of the material in the quantum-well layer 230.

In the present specification, the term “quantum well” refers to a potential well that confines charge carriers or charged particles such as electrons and holes to a substantially two-dimensional planar region. In a semiconductor light emission device, the quantum well can trap excited electrons and holes and define the wavelength of light emission when the electrons and the holes recombine in the quantum well and produce photons.

In the present specification, a quantum-well layer can include a uniform layer or a plurality of quantum wells. For example, a quantum-well layer (e.g., layer 230) can include a substantially uniform layer made of InN, GaN, InGaN, AlGaN, InAlN, or AlInGaN. A quantum-well layer can also include a multi-layer structure defining one or more quantum wells. A quantum well can for example be formed by an InGaN, an AlGaN, an InAlN, or an InGaAlN layer sandwiched in between two GaN layers. A quantum well can also be formed by an InGaN layer sandwiched in between GaN or AlGaN layers. The quantum-well layer can include one or a stack of such layered structure each defining a quantum well as described above.

The bandgap for InN is about 1.9 eV, lower than the bandgap for GaN that is at about 3.4 eV. The lower bandgap of the InN or the InGaN layer can define a potential well for trapping charge carriers such as electrons and holes. The trapped electrons and holes can recombine to produce photons (light emission). The bandgap in the InN or the InGaN layer can therefore determine the colors of the light emissions. In other words, the colors of light emissions can be tuned by adjusting the compositions of In and Ga in InGaN. For example, a quantum well can produce red light emission from an InN layer, green light emission from an In(0.5)Ga(0.5)N layer, and blue light emission from an In(0.3)Ga(0.7)N in the quantum-well.

In one aspect, the disclosed light emission device can include a semiconductor substrate having at least two top surfaces that are not parallel to each other; and a light emission layer disposed over one of those top surfaces to emit light, the light emission layer having a light emission surface which is not parallel to one of the above-mentioned top surfaces of the substrate. By stating that one layer is disposed “over” or “above” another layer, this does not necessarily mean that the two layers must be in direct contact with each other; indeed, there may be one or more additional layers in between, as will be further apparent from other portions of this description. In another aspect, the disclosed light emission device can include a substrate; and a light emission layer disposed over the substrate to emit light, the light emission layer having a footprint area and having a light emission surface area which is greater than the footprint area. In another aspect, the disclosed light emission device can include a substrate having a top surface and a protrusion formed on the top surface; and a light emission layer disposed on the protrusion to emit light, the light emission layer having a light emission surface which is not parallel to the above-mentioned top surface of the substrate.

The light emission devices 200 on the wafer 700 can be used collectively as an integrated light emission device. Alternatively, light emission devices 200 on the wafer 700 can be separated by dicing and cutting (e.g., along dicing line 285 in FIG. 8) to form individual light emission devices, each of which can be powered to emit light in separate applications. Note, however, that before dicing, the upper electrodes 260 of the light emission devices 200 on the wafer 700 are physically contiguous and electrically form a single node, which allows them to be connected to a common external electrode, such as for testing purposes. Similarly, before dicing the lower electrodes 270 of the light emission devices 200 are physically contiguous and electrically form a single node, which allows them to be connected to a second common external electrode, such as for testing purposes.

Referring to FIGS. 6A, 9A through 9C, and 10, the fabrication process of the light emission device 200 will now be further described, according to one embodiment. The end result of the fabrication process is shown schematically in FIG. 6A as light emission device 200. It should be noted that the process is described using trenches as an example for the light emission structure. However, the process is also applicable to other types of light emission structures, such as protrusions (e.g. pyramids) and other different structures that include sloped surfaces not parallel to their respective upper surfaces of the substrates.

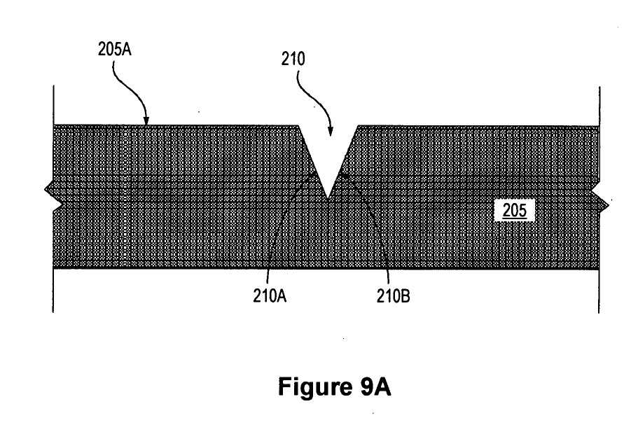

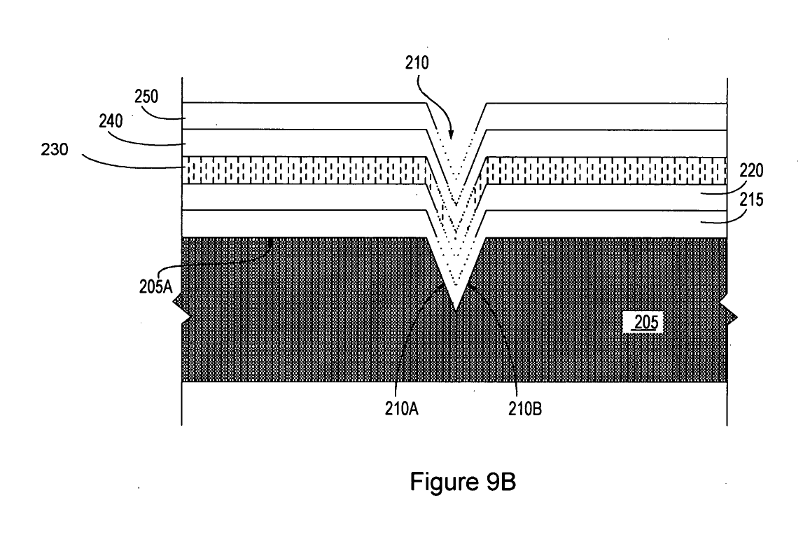

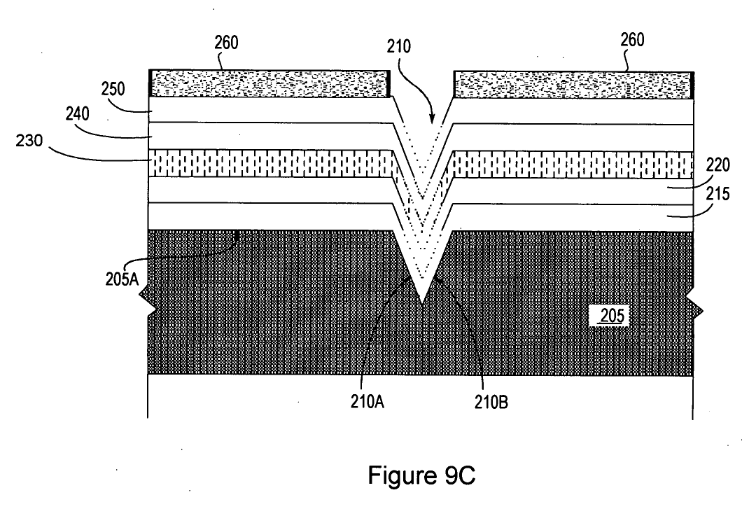

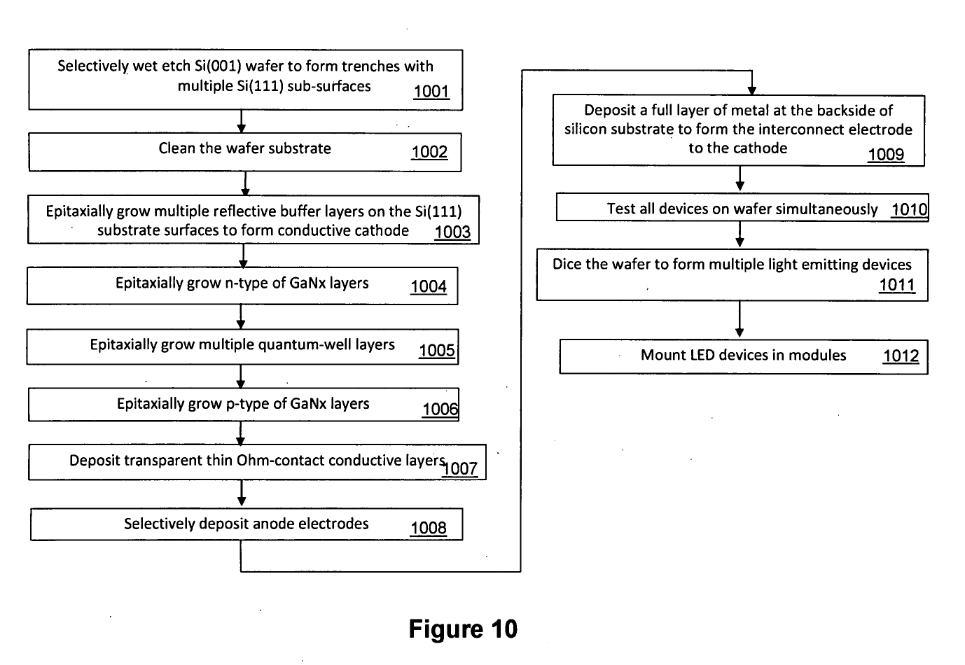

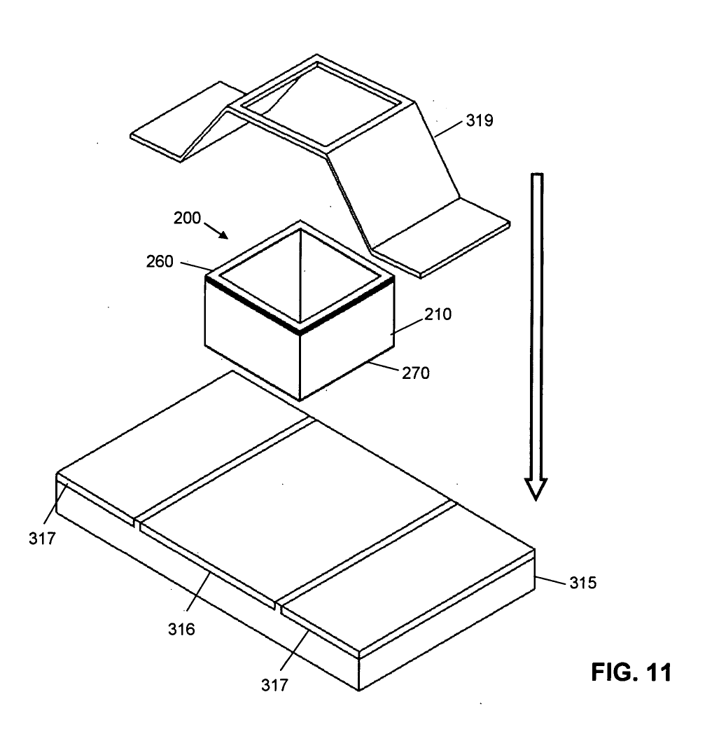

Referring to FIG. 10, initially, at step 1001 in the fabrication process, a crystal directional selective wet etch is performed on a top surface of a Si (001) wafer to form trenches 210 with multiple Si (111) sub-surfaces, as shown in FIG. 9A, for plurality of light emission devices 200. In an embodiment where the semiconductor substrate 205 is doped so as to be electrically conductive, it is not necessary in step 1001 to etch completely through to the bottom surface of the substrate 205, where the cathode 270 will be formed. That is, a gap can exist between the bottom of the trench 210 and the bottom surface of the substrate 205. However, in an embodiment in which the semiconductor substrate 205 is not doped and is therefore not conductive, the substrate 205 is etched completely through to the bottom surface of the substrate 205 in step 1001, so that the subsequently formed conductive reflective layer 215 can come into contact with the subsequently formed cathode 270, as illustrated in FIG. 6B.

Next, at step 1002 the wafer substrate is cleaned by any known or convenient method. At 1003, multiple reflective buffer layers 215 are grown epitaxially on the top surface 205A (111 surface) of the Si substrate (and in the trenches 210) to form the conductive reflection layers for the specific wavelength of light emitted devices (FIG. 9B). In order to form the conductive reflective buffer layer, multiple thin-films of metals and its nitrides are deposited alternatively to form the total internal reflection structures. For example, a 20A of Al on top of 25A of AlNx can be deposited repeatedly for 10 times to form a single reflective buffer layer.

At 1004 an n-type GaNx layer 220 is then grown on the top buffer layer 215. At 1005 multiple quantum well layers 230 are epitaxially grown on the n-type GaNx layer 220. Next, at 1006 a p-type GaNx layer 240 is epitaxially grown on the top quantum well layer 230. A thin ohm-contact conductive layer 250, such as ITO, is then deposited on top of the p-type GaNx layer at 1007, as shown in FIG. 9B. At 1008, the anode electrode contacts 260 are selectively deposited on top of the ohm-contact conductive layer, as shown in FIG. 9C.

Next, at 1009 a full layer of metal is deposited on the (etched) bottom surface of a silicon substrate to form the interconnect electrode 270 to the cathode, as shown in FIG. 6. This completes the fabrication of the light emission devices at the wafer level.

Next, the testing phase begins. In one embodiment, at 1010 all of the light emission devices constructed on the wafer are tested simultaneously on the wafer to detect manufacturing defects and to determine their device characteristics. Aside from the fact that all devices are tested simultaneously, any known or convenient testing techniques can be used. Next, at 1011 the wafer is diced to form multiple physically separate light emission devices. Each resulting die is immediately ready for module packaging at this point. Therefore, in the packaging stage at 1012, those devices (dice) which successfully passed the testing phase are packaged into light emission device modules. An example of such a module is illustrated in FIG. 11.

Referring to FIG. 11, a light emission device (die) 200 fabricated as described above can be directly mounted onto a mounting substrate 315 (e.g., a heat sink), without the use of any wire bonding. The mounting substrate 315 may be, for example, a ceramic heat sink. Metal contacts for the anode and cathode may be formed directly on a surface of the mounting substrate 315. For example, as shown in FIG. 11, contact 316 on the mounting substrate 315 is a contact for the cathode 270, while contacts 317 are contacts for the anode 360. Because contact between the device 200 and the mounting substrate 315 is through the entire electrode surfaces, this configuration provides high thermal dissipation. A fastener 313, which may be a metal spring cap for example, can be used to clamp the device 200 directly onto the mounting substrate 315.

Although the present invention has been described with reference to specific exemplary embodiments, it will be recognized that the invention is not limited to the embodiments described, but can be practiced with modification and alteration within the spirit and scope of the appended claims. Accordingly, the specification and drawings are to be regarded in an illustrative sense rather than a restrictive sense.

What is claimed is:

1. A semiconductor device comprising:
a semiconductor substrate having a first surface and a second surface;
a light emission layer having a light emission surface which is not parallel to the first surface or the second surface; and
a first electrode and a second electrode, formed on opposite surfaces of the substrate, to pass current through the light emission layer to cause the light emission layer to emit light.

2. A semiconductor device as recited in claim 1, further comprising an electrically conductive light reflective layer disposed between the light emission layer and the second surface.

3. A semiconductor device as recited in claim 2, wherein the semiconductor substrate is doped so as to be electrically conductive.

4. A semiconductor device as recited in claim 2, wherein the semiconductor substrate is not doped.

5. A semiconductor device as recited in claim 1, wherein the first and second electrodes are disposed on opposite sides of the light emission layer.

6. A semiconductor device as recited in claim 1, wherein the first or second surface is parallel to a (100) crystalline plane of the semiconductor substrate.

7. A semiconductor device as recited in claim 6, wherein the light emission layer is parallel to a (111) crystalline plane of the semiconductor substrate.

8. A semiconductor device as recited in claim 1, wherein the light emission layer comprises a Group III-V compound layer.

9. A semiconductor device comprising:
an electrically conductive doped semiconductor substrate having a first surface and a second surface;
a quantum well layer which is not parallel to the first surface or the second surface;
an electrically conductive reflective layer disposed between the quantum well layer and the second surface;
a first electrode and a second electrode, formed on opposite surfaces of the device, to pass current through the quantum well layer to cause the quantum well layer to emit light.

10. A light emission device as recited in claim 9, wherein the electrode layer is a Group III-V compound layer.

11. A light emission device as recited in claim 10, wherein one of the electrode layer comprises a light reflective buffer layer.

12. An apparatus comprising:
a plurality of substantially identical light emitting devices formed on a semiconductor substrate, each of the plurality of light emitting devices including
a plurality of layers formed on a first surface of the substrate, including a first layer and a plurality of light emitting layers; and
a first electrode formed on the first device and shared by all of the plurality of devices.

13. An apparatus as recited in claim 12, further comprising a second electrode shared by all of the plurality of devices.

14. An apparatus as recited in claim 13, wherein the second electrode is formed on a second surface of the substrate which is parallel and opposite to the first surface of the substrate.

15. An apparatus as recited in claim 14, wherein the plurality of layers further include a second layer, and the second electrode is electrically coupled to the second layer.

16. An apparatus as recited in claim 12, wherein each of the light emitting devices is a light emitting diode.

17. An apparatus comprising:
a plurality of light emitting diodes formed on a semiconductor substrate, each of the plurality of light emitting diodes including
a plurality of device layers formed on a top surface of the substrate; and
a first electrode formed on a bottom surface of the substrate and shared by all of the plurality of devices.

18. An apparatus as recited in claim 17, further comprising:
a second electrode shared by all of the plurality of devices.

19. An apparatus as recited in claim 18, wherein the bottom surface of the substrate is parallel and opposite to the top surface of the substrate.

20. An apparatus as recited in claim 19, wherein the second electrode is formed on a first device layer of the plurality of device layers.

21. An apparatus as recited in claim 20, wherein the plurality of device layers further include a second device layer and the first electrode is electrically coupled to the second device layer.

22. A method comprising:
forming a plurality of light emitting diodes on a semiconductor wafer;
prior to dicing of the semiconductor wafer, simultaneously testing all of the plurality of light emitting diodes for manufacturing defects; and
dicing the semiconductor wafer to produce a plurality of physically separate light emitting diodes.

23. A method as recited in claim 22, further comprising:
performing a burn-in process prior to said dicing.

24. A method as recited in claim 22, further comprising:
in response to detecting a defect during said testing, performing a repair process to repair the defect, prior to said dicing.

25. A method as recited in claim 22, wherein forming the plurality of light emitting diodes on the semiconductor wafer comprises:
forming the plurality of light emitting diodes to include
a plurality of device layers formed on a top surface of the substrate;
a first electrode formed on a bottom surface of the substrate and shared by all of the plurality of devices; and
a second electrode shared by all of the plurality of devices.

26. A method as recited in claim 25, wherein the bottom surface of the substrate is parallel and opposite to the top surface of the substrate.

27. A method as recited in claim 26, wherein the second electrode is formed on a first device layer of the plurality of device layers.

28. A method as recited in claim 27, wherein the plurality of device layers further include a second device layer and the first electrode is electrically coupled to the second device layer.

29. A light emission module comprising:
a mounting substrate which includes a heat sink;
a light emitting diode disposed on the mounting substrate;
a fastener which attaches the light emitting diode to the mounting substrate, wherein the light emitting diode is electrically connected to contacts on the mounting substrate without any wire bonding.

30. A light emission module as recited in claim 29, wherein the fastener is electrically connected to a first electrode of the light emitting diode and to a first electrical contact on the mounting substrate.

31. A light emission module as recited in claim 30, wherein a second electrode of the light emitting diode is electrically connected to a second electrical contact on the mounting substrate.

32. A light emission module as recited in claim 31, wherein the first electrode of a light emitting diode is on a first surface of the light emitting diode, the second electrode of the light emitting diode is on a second surface of the light emitting diode, and the second surface is parallel and opposite to the first surface.

33. A light emission module as recited in claim 29, wherein the fastener comprises a clamping mechanism.

34. A light emission module as recited in claim 29, wherein the fastener comprises a metal spring cap.
